(19) United States
(12) Patent Application Publication
(10) Pub. No.: US 2007/0284760 A1
(43) Pub. Date: Dec. 13, 2007

(54) Chip and flat panel display apparatus comprising the same

(76) Inventors: Eun-Ah Kim, Suwon-si (KR); Byung-Hee Kim, Suwon-si (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/784,309

(22) Filed: Apr. 6, 2007

(30) Foreign Application Priority Data
Jun. 7, 2006 (KR) 10-2006-0050874

(51) Int. Cl. H01L 23/29

(52) U.S. Cl. 257/789

(57) ABSTRACT

A chip electrically connected to wires on a substrate without errors and a flat panel display apparatus including the chip is provided. The chip includes a plurality of bumps that protrude from the chip and have different heights. The flat panel display apparatus may include pads with variable heights on the top of wires of the apparatus.

### CROSS-REFERENCE TO RELATED PATENT APPLICATION

This application claims the benefit of Korean Patent Application No. 10-2006-0050874, filed on Jun. 7, 2006, in the Korean Intellectual Property Office, the disclosure of which is incorporated herein in its entirety by reference.

### BACKGROUND

1. Field

The present invention relates to a chip and a flat panel display apparatus including the chip, and more particularly, to a chip electrically connected to wires on a substrate without errors and a flat panel display apparatus including the chip.

2. Description of the Related Art

As for flat panel display apparatuses, research into technology of arranging a chip, such as, an integrated circuit, directly on a substrate without interposing a printed circuit board (PCB) or the like between the chip and the substrate has been actively conducted. In other words, research into a flat panel display apparatus made compact and thin by electrically connecting the chip directly to the wires on the substrate has been actively conducted.

### SUMMARY

The present invention provides a chip electrically connected to wires on a substrate without errors and a flat panel display apparatus including the chip.

A flat panel display device comprises a substrate, a chip, and a plurality of wires. The substrate comprises a top surface. The chip comprises a bottom surface and a plurality of bumps on the bottom surface, and the plurality of bumps comprise a first bump and a second bump, each bump comprising a bottom surface. The plurality of wires are interposed between the top surface of the substrate and the bottom surface of the chip, and the plurality of wires comprises a first wire and a second wire, each wire comprising a top surface,

The first wire is aligned with the first bump in a direction substantially perpendicular to the top surface of the substrate and the second wire is aligned with the second bump in said direction, and a first interval between the top surface of the first wire and the bottom surface of the first bump is substantially identical to a second interval between the top surface of the second wire and the bottom surface of the second bump.

The device may further comprise a selective conduction film, and the selective conduction film is interposed between the wires and bumps such that aligned pair of wire and bump are electrically connected to each other. The selective conduction film may comprise an anisotropic conduction film. The selective conduction film may comprise a plurality of conductive spacers, each of which having a spacing size by which the conductive spacer keeps two planes apart from each other.

The spacing size of the conductive spacer may be larger than the interval between the aligned pair of wire and bump. The conductive spacers may comprise a plurality of conductive beads having a diameter, and the diameter is larger than the interval between the aligned pair of wire and bump. The conductive beads may be elastic.

The device of Claim 1, wherein a first distance between the top surface of the substrate and the top surface of the first wire are different from the second distance between the top surface of the substrate and the top surface of the second wire.

A first distance between the top surface of the substrate and the top surface of the first wire may be substantially identical to a second distance between the top surface of the substrate and the top surface of the second wire.

Each of at least part of the wires may comprise a conductive pad formed at a top portion of the wire.

The device may further comprise a display unit interposed between the substrate and the chip, and the display unit comprises a first layer having a first height from the top surface of the substrate and a second layer having a second height from the top surface of the substrate.

The first wire is formed on the first layer of the display unit and the second wire is formed on the second layer of the display unit. The first height may be different from the second height. The first height may be substantially same as the second height.

A first distance between the top surface of the substrate and the top surface of the first wire may be different from the second distance between the top surface of the substrate and the top surface of the second wire. Alternatively, the first distance between the top surface of the substrate and the top surface of the first wire may be substantially identical to the second distance between the top surface of the substrate and the top surface of the second wire.

The display unit is formed on at least part of the top surface of the substrate, and the first layer formed on at least part of the top surface of the substrate and the second layer formed on at least part of the top surface or on at least part of the first layer.

The first distance between the top surface of the substrate and the bottom surface of the first bump may be different from the second distance between the top surface of the substrate and the bottom surface of the second bump.

The first distance between the top surface of the substrate and the bottom surface of the first bump may be substantially identical to the second distance between the top surface of the substrate and the bottom surface of the second bump.

A method of fabricating a flat panel display device may comprise: providing the substrate comprising a top surface; providing the chip comprising a bottom surface with the plurality of bumps thereon; providing the plurality of wires above the top surface of the substrate, whereby each of the plurality of bumps on the bottom surface of the chip accommodates height of the wire in a corresponding location such that an interval between the top surface of each wire and the bottom surface of its corresponding bump is substantially same when aligned substantially parallel with the top surface of the substrate and the bottom surface of the chip facing each other; and mounting the chip on the substrate by interposing a selective conductive film comprising a plurality of conductive beads between the substrate and the chip.

The method may further comprise, prior to providing chip, providing at least some of the plurality of layers on at least a part of the top surface of the substrate, and each of the plurality of layers comprises a top surface.

The method may further comprise, prior to mounting the chip on the substrate, providing at least some of the plurality of wires on the top surface of the plurality of layers. Each of the plurality of bumps on the bottom surface of the chip accommodates height of the top surface of the wire from the top surface of the substrate in a corresponding location such that an interval between the top surface of each wire and the bottom surface of its corresponding bump is substantially same when aligned substantially parallel with the top surface of the substrate and the bottom surface of the chip facing each other.

The method may further comprise, prior to mounting the chip on the substrate, providing a plurality of pads above the top surface of at least some of the plurality of wires. Each of the plurality of pads accommodates sum of height of top surface of a wire from the top surface of the substrate and height of the bottom surface of its corresponding bump such that an interval between the top surface of each pad and the bottom surface of its corresponding bump is substantially same when aligned substantially parallel with the top surface of the substrate and the bottom surface of the chip facing each other.

At least part of the plurality of wires is provided on one or more layers formed on the top surface of the substrate or on a top surface of the one or more layers. The plurality of wires have substantially identical heights, and wherein the plurality of bumps have substantially identical heights.

According to an aspect of the present invention, there is provided a chip comprising a plurality of bumps that protrude from the chip and have different heights.

The heights from one side of the chip to end surfaces of the bumps may be different.

According to another aspect of the present invention, there is provided a flat panel display apparatus comprising: a substrate; a display unit arranged on the substrate; a plurality of wires arranged on the substrate; and a chip having bumps electrically connected to the wires, wherein heights from a top surface of the substrate to top surfaces of the wires are different, heights of the bumps protruding from the chip are different, and distances between the top surfaces of the wires and end surfaces of the bumps electrically connected to the wires are constant.

Levels over the top surface of the substrate at which the wires are arranged may be different.

The wires may be formed of different materials.

Heights from one surface of the chip to the end surfaces of the bumps may be different.

The bumps of the chip may be electrically connected to the wires by a conduction film.

The conduction film may comprise a plurality of conductive spacers.

Distances between the top surfaces of the wires and the end surfaces of the bumps electrically connected to the wires may be less than or equal to a diameter of each of the conductive spacers included in the conduction film.

The flat panel display apparatus may further include, within or outside the display unit, thin film transistors, each including: a semiconductor layer; a gate insulation film on the semiconductor layer; a gate electrode on the gate insulation film; an interlayer insulation film covering the gate electrode; and source and drain electrodes contacting the semiconductor layer via contact holes that are formed in the gate insulation film and the interlayer insulation film, wherein some of the wires are arranged on the same level as the gate electrode, and some of the others are arranged on the same level as the drain electrode.

A sub-pixel of the display unit may include: a pixel electrode; a facing electrode facing the pixel electrode; and an intermediate layer interposed between the pixel electrode and the opposite electrode, comprising at least a light-emitting layer, wherein some of the wires are arranged at the same level as the pixel electrode.

According to another aspect of the present invention, there is provided a flat panel display apparatus including: a substrate; a display unit arranged on the substrate; a plurality of wires arranged on the substrate; and a chip having bumps electrically connected to the wires by a conduction film comprising conductive spacers, wherein heights from a top surface of the substrate to top surfaces of the wires are different, heights of the bumps protruding from the chip are different, and distances between the top surfaces of the wires and end surfaces of the bumps electrically connected to the wires are less than or equal to a diameter of each of the conductive spacers of the conduction film.

Levels over the top surface of the substrate at which the wires are arranged may be different.

The wires may be formed of different materials.

Heights from one surface of the chip to the end surfaces of the bumps may be different.

The flat panel display apparatus may further include, within or outside the display unit, thin film transistors, each including: a semiconductor layer; a gate insulation film on the semiconductor layer; a gate electrode on the gate insulation film; an interlayer insulation film covering the gate electrode; and source and drain electrodes contacting the semiconductor layer via contact holes that are formed in the gate insulation film and the interlayer insulation film, wherein some of the wires are arranged on the same level as the gate electrode, and some of the others are arranged on the same level as the drain electrode.

A sub-pixel of the display unit may include: a pixel electrode; a facing electrode facing the pixel electrode; and an intermediate layer interposed between the pixel electrode and the opposite electrode, comprising at least a light-emitting layer, wherein some of the wires are arranged at the same level as the pixel electrode.

The conductive spacers may be elastic.

According to another aspect of the present invention, there is provided a flat panel display apparatus including: a substrate; a display unit arranged on the substrate; a plurality of wires arranged on the substrate; a chip having bumps electrically connected to the wires; pads interposed between the wires and the bumps of the chip, wherein heights from a top surface of the substrate to top surfaces of the wires are different, the pads are arranged on the top surfaces of the wires and have lengths so that heights from the top surface of the substrate to surfaces of the pads facing the bumps of the chip are constant, and heights of the bumps protruding from the chip are constant.

The pads may be conductive.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic cross-section of a part of a flat panel display apparatus;

FIG. 2 is a schematic cross-section of a part of another flat panel display apparatus;

FIG. 3 is a schematic cross-section of a chip according to an embodiment of the present invention;

FIG. 4 is a schematic cross-section of a part of a flat panel display apparatus according to another embodiment of the present invention;

FIG. 5 is a schematic cross-section of a part of a flat panel display apparatus according to another embodiment of the present invention;

FIG. 6 is a schematic cross-section of a part of an organic light emitting display device according to an embodiment of the present invention; and

FIG. 7 is a schematic cross-section of a part of a flat panel display apparatus according to another embodiment of the present invention.

### DETAILED DESCRIPTION OF THE INVENTION

The present invention will now be described more fully with reference to the accompanying drawings, in which exemplary embodiments of the invention are shown.

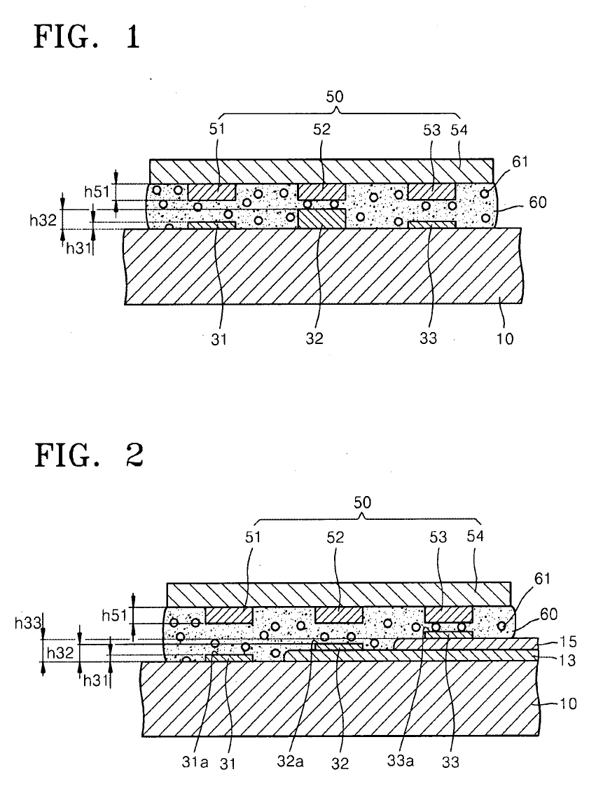

FIG. 1 is a schematic cross-section of a part of a flat panel display apparatus. Referring to FIG. 1, wires 31, 32, and 33 are formed on a substrate 10. The wires 31, 32, and 33 are electrically connected to a chip 50 by using an anisotropic conduction film (ACF) 60. In other words, the ACF 60 is formed on the wires 31, 32, and 33, and the chip 50 is arranged on the ACF 60 and pressed down and heated by a bar having a heating unit.

In this case, the ACF 60 includes conductive spacers 61. The conductive spacers 61 are interposed between bumps 51, 52, and 53 of the chip 50 and the wires 31, 32, and 33 so that the wires 31, 32, 33 are electrically connected to the chip 50.

However, in the flat panel display apparatus, the wires 31, 32, and 33 may have different thicknesses as illustrated in FIG. 1. In FIG. 1, thicknesses h31 of the wires 31 and 33 are smaller than a thickness h32 of the wire 32. However, as illustrated in FIG. 1, heights h51 of the bumps 51, 52, and 53 with respect to a chip main body 54 are the same. Hence, only the bump 52 among the bumps 51, 52, and 53 of the chip 50 is electrically connected to the wire 32 via the conductive spacers 61, and the other bumps 51 and 53 fail to be electrically connected to the wires 31 and 33.

In FIG. 2, which is a schematic cross-section of a part of another flat panel display apparatus, wires 31, 32, and 33 have the same thickness, and they are arranged at different heights. Hence, even when the wires 31, 32, and 33 have the same thickness, some of them fail to be electrically connected to the chip 50, like the flat panel display apparatus of FIG. 1.

In other words, the wire 31 may be directly formed on the substrate 10, the wire 32 may be formed on a layer 13 formed on the substrate 10, and the wire 33 may be formed on a layer 15 formed on the layer 13 on the substrate 10.

In this case, heights h31, h32, and h33 from the substrate 10 to the upper surfaces 31a, 32a, and 33a of the wires 31, 32, and 33 are different. However, as illustrated in FIG. 2, all of the bumps 51, 52, and 53 have the same height, i.e., a height h51, with respect to the chip main body 54. Hence, only the bump 53 of the bumps 51, 52, and 53 is electrically connected to the wire 33 via conductive spacers 61, that is, the other bumps 51 and 52 fail to be electrically connected to the wires 31 and 32.

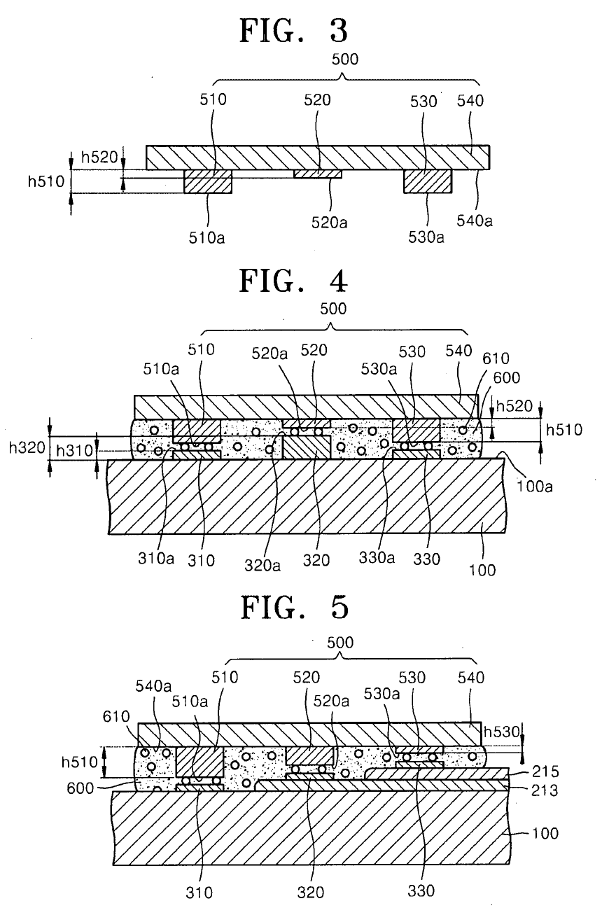

FIG. 3 is a schematic cross-section of a chip 500 according to an embodiment of the present invention. Referring to FIG. 3, the chip 500 includes a plurality of bumps 510, 520, and 530. Heights of the bumps 510, 520, and 530 from the chip 500 are different. In other words, heights of the bumps 510, 520, and 530, namely, lengths from one surface 540a of a chip main body 540 of the chip 500 to end surfaces 510a, 520a, and 530a of the bumps 510, 520, and 530, are different. In FIG. 3, the bumps 510 and 530 have the same height, i.e., a height h510, but the bump 520 has a height h520 which is different from the height h510.

The reason why the heights of bumps of a chip are made different is that wires of a flat panel display apparatus that are to be electrically connected to the bumps have different thicknesses or the wires are disposed at different levels. Hence, in an embodiment of the present invention, the heights of the bumps of the chip are adjusted to be different in consideration of the thicknesses of the wires of the flat panel display apparatus to be electrically connected to the bumps of the chip or the positions where the wires are to be arranged, so that the electrical connection of the bumps of the chip to the wires can be secured. This feature of the present invention will be described in greater detail with reference to embodiments to be described later.

FIG. 4 is a schematic cross-section of a part of a flat panel display apparatus according to another embodiment of the present invention. The flat panel display apparatus of FIG. 4 includes a substrate 100, a display unit (not shown), and a plurality of wires 310, 320, and 330. The display unit and the wires 310, 320, and 330 are arranged on the substrate 100. The wires 310, 320, and 330 are electrically connected to the display unit or to a driving circuit outside the display unit. Heights from a top surface 100a of the substrate 100 to top surfaces 310a, 320a, and 330a of the wires 310, 320, and 330 are different. More specifically, in FIG. 4, heights h310 of the wires 310 and 330 are different from a height h320 of the wire 320.

The wires 310, 320, and 330 are electrically connected to a chip 500, more specifically, to bumps 510, 520, and 530, respectively, of the chip 500. Heights of the bumps 510, 520, and 530, which protrude from a main body 540 of the chip 500, are different. More specifically, in FIG. 4, heights h510 of the bumps 510 and 530 are different from a height h520 of the bump 520. In other words, heights from surfaces of the bumps 510, 520, and 530 of the chip 500 in contact with the main body 540 to end surfaces 510a, 520a, and 530a of the bumps 510, 520, and 530 are different.

In this structure, distances between the top surfaces 310a, 320a, and 330a of the wires 310, 320, and 330 and the end surfaces 510a, 520a, and 530a of the bumps 510, 520, and 530 electrically connected to the wires 310, 320, and 330 are constant. In other words, when the height h320 of the wire 320 is large, the height h520 of the bump 520 corresponding to the height h320 is small. When the height h310 of the wire 310 is small, the height h510 of the bump 510 corresponding to the height h310 is large. Accordingly, the distances between the top surfaces 310a, 320a, and 330a of the wires 310, 320, and 330 and the end surfaces 510a, 520a, and 530a of the bumps 510, 520, and 530 electrically connected to the wires 310, 320, and 330 are constant.

In a chip, the heights of bumps are constant. Hence, when the thick nesses of wires to be connected to the bumps are different, some of the bumps may not be electrically connected to the corresponding wires. However, in the flat panel display apparatus of FIG. 4, the heights of the bumps 510, 520, and 530 of the chip 500 correspond to the thickness of the wires 310, 320, and 330, respectively, so that all of the bumps 510, 520, and 530 of the chip 500 can be electrically connected to the wires 310, 320, and 330, respectively.

To electrically connect the bumps 510, 520, and 530 of the chip 500 to the wires 310, 320, and 330, respectively, an anisotropic conduction film (ACF) 600 is interposed between the bumps 510, 520, and 530 and the wires 310, 320, and 330. Of course, various conduction films other than the ACF 600 may be used. The ACF 600 includes a plurality of conductive spacers 610. The conductive spacers 610 are elastic, and are interposed between the bumps 510, 520, and 530 and the wires 310, 320, and 330 in order to electrically connect the bumps 510, 520, and 530 of the chip 500 to the wires 310, 320, and 330, respectively.

In this embodiment where the bumps 510, 520, and 530 of the chip 500 are electrically connected to the wires 310, 320, and 330 via the conductive spacers 610 of the ACF 600, the constant distances between the top surfaces 310a, 320a, and 330a of the wires 310, 320, and 330 and the end surfaces 510a, 520a, and 530a of the bumps 510, 520, and 530 may be set to be less than or equal to a diameter of the conductive spacers 610.

FIG. 5 is a schematic cross-section of a part of a flat panel display apparatus according to another embodiment of the present invention. The flat panel display apparatus of FIG. 5 is different from that of FIG. 4 in that the wires 310, 320, and 330 are arranged at different levels over the top surface 100a of the substrate 100. In FIG. 5, the wire 310 is arranged on the substrate 100, the wire 320 is arranged on a layer 213 formed on the substrate 100, and the wire 330 is arranged on a layer 215 formed on the layer 213 on the substrate 100. In this case, the wires 310, 320, and 330 may be formed of different materials.

When the wires 310, 320, and 330 are arranged on different levels from the top surface 100a of the substrate 100 although they have the same thickness, if the bumps 510, 520, and 530 protruding from the main body 540 of the chip 500 have the same height, some of the bumps 510, 520, and 530 may not be electrically connected to corresponding ones of the wires 310, 320, and 330.

Hence, by differentiating the heights of the bumps 510, 520, and 530, distances between the top surfaces 310a, 320a, and 330a of the wires 310, 320, and 330 and the end surfaces 520a, 520a, and 530a of the bumps 510, 520, and 530 can be made constant. In other words, as illustrated in FIG. 5, a height h530 of the bump 530 corresponding to the wire 330 arranged on the layer 215 formed on the substrate 100 is small, and a height h510 of the bump 510 corresponding to the wire 310 arranged on the substrate 100 is large. Thus, the distances between the top surfaces 310a, 320a, and 330a of the wires 310, 320, and 330 and the end surfaces 510a, 520a, and 530a of the bumps 510, 520, and 530 become constant.

As described above, in the flat panel display apparatus of FIG. 5, the heights of the bumps 510, 520, and 530 of the chip 500 depend on the levels at which the wires 310, 320, and 330 are arranged. Accordingly, all of the bumps 510, 520, and 530 of the chip 500 can be electrically connected to the corresponding wires 310, 320, and 330, respectively.

Of course, in this embodiment, the ACF 600 may be interposed between the bumps 510, 520, and 530 and the wires 310, 320, and 330 in order to electrically connect the bumps 510, 520, and 530 to the wires 310, 320, and 330. In this embodiment where the bumps 510, 520, and 530 of the chip 500 are electrically connected to the wires 310, 320, and 330 via the conductive spacers 610 of the ACF 600, the constant distances between the top surfaces 310a, 320a, and 330a of the wires 310, 320, and 330 and the end surfaces 510a, 520a, and 530a of the bumps 510, 520, and 530 may be set to be less than or equal to a diameter of the conductive spacers 610.

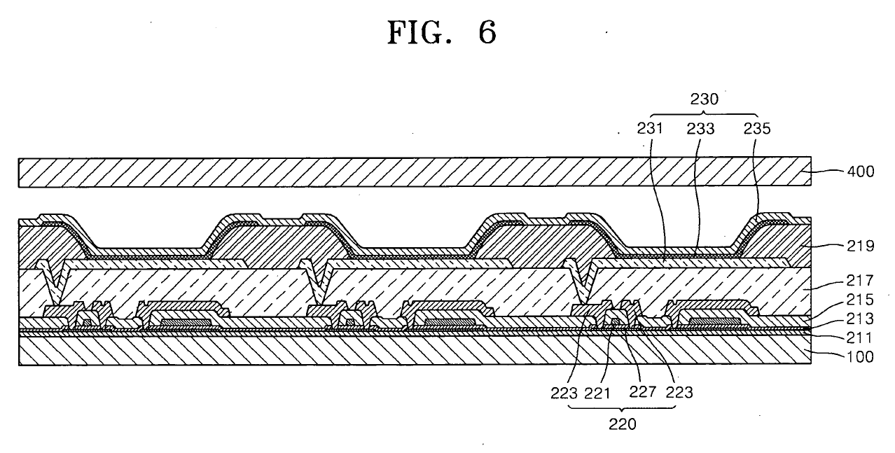

The reason why the wires 310, 320, and 330 on the substrate 100 can be arranged at different levels is that they can be formed simultaneously with the formation of members installed in or outside the display unit. Referring to FIG. 6, schematically illustrating a part of a display unit of an organic light emitting display apparatus according to an embodiment of the present invention, the display unit includes thin film transistors (TFTs) 220 and organic light emitting devices 230 electrically connected to the TFTs 220.

As illustrated in FIG. 6, the TFTs 220 are installed on a substrate 100, and the organic light emitting devices 230 are installed over the TFTs 220. Each of the organic light emitting devices 230 includes a pixel electrode 231 electrically connected to each of the TFTs 220, a facing electrode 235 installed across the entire surface of the substrate 100, and an intermediate layer 233 arranged between the pixel electrode 231 and the facing electrode 235 and including at least a light emitting layer. Each of the pixel electrodes 231 is included in each pixel (or each sub-pixel).

Each of the TFTs 220 installed on the substrate 100 includes a gate electrode 221, source and gate electrodes 223, a semiconductor layer 227, a gate insulation film 213, and an interlayer insulation film 215. The shape of the TFTs 220 is not limited to the embodiment illustrated in FIG. 6. In other words, various TFTs, such as, an organic TFT in which the semiconductor layer 227 is formed of an organic material, a silicon TFT in which the semiconductor layer 227 is formed of silicon, etc., may be used. As in the embodiment of FIG. 6, a buffer layer 211 formed of silicon oxide, silicon nitride, or the like may be further included between the TFTs 220 and the substrate 100 as needed.

The pixel electrode 231 and the facing electrode 235 of each of the organic light emitting devices 230 face each other. The intermediate layer 233 of each of the organic light emitting devices 230 is formed of an organic material and may include a plurality of layers. These layers will be described later.

The pixel electrode 231 serves as an anode electrode, and the facing electrode 235 serves as a cathode electrode. Of course, the pixel electrode 231 may serve as a cathode electrode, and the facing electrode 235 may serve as an anode electrode.

The pixel electrode 231 may be a transparent electrode or a reflective electrode. When the pixel electrode 231 is implemented as a transparent electrode, it may be formed of ITO, IZO, ZnO, or In₂O₃. When the pixel electrode 231 is implemented as a reflective electrode, it may include a reflection film formed of Ag, Mg, Al, Pt, Pd, Au, Ni, Nd, Ir, Cr, or a compound of these elements, and a film formed of ITO, IZO, ZnO, or In₂O₃ on the reflection film.

The facing electrode 235 may also be a transparent electrode or a reflective electrode. When the facing electrode 235 is implemented as a transparent electrode, it may include a film formed of Li, Ca, LiF/Ca, LiF/Al, Al, Mg, or a compound of these elements deposited to face the intermediate layer 233 between the pixel electrode 231 and the facing electrode 235, and an auxiliary electrode or a bus electrode line formed of a material used to form the transparent electrode, such as, ITO, IZO, ZnO, or In₂O₃, on the film. When the facing electrode 235 is implemented as a reflective electrode, it may be formed of Li, Ca, LiF/Ca, LiF/AI, Al, Mg, or a compound of these elements.

A pixel defining layer (PDL) 219 covers the edges of the pixel electrodes 231 and has a predetermined thickness. In other words, the PDL 219 covers the edges of the pixel electrodes 231 and the spaces between the pixel electrodes 231 except for the centers of the pixel electrodes 231. The PDL 219 functions to define light emitting areas and also to prevent a short-circuit between the pixel electrode 231 and the facing electrode 235 by preventing concentration of an electric field on the edges of the pixel electrodes 231 by widening the intervals between the edges of the pixel electrodes 231 and the facing electrodes 235.

The intermediate layer 233 formed between the pixel electrodes 231 and the facing electrode 235 and having at least a light-emitting layer may be formed of various materials, such as, a small molecular organic material or a polymer organic material.

When the intermediate layer 233 is formed of a small molecular organic material, it may be formed by stacking a hole injection layer (HIL), a hole transport layer (HTL), an organic emission layer (EML), an electron transport layer (ETL), and an electron injection layer (EIL) in a single or complex layer structure. Various organic materials, such as, copper phthalocyanine (CuPc), N,N′-Di(naphthalene-1-yl)-N,N′-diphenyl-benzidine (NPB), tris-8-hydroxyquinoline aluminum (Alq3), etc., may be used as the organic material. These small molecular organic materials may be, for example, deposited according to a vapor deposition technique using a mask.

When the intermediate layer 233 is formed of a polymer organic material, it may be typically formed by stacking a hole transport layer (HTL) and an organic emission layer (EML). PEDOT is used to form the HTL, and a polymer organic material, such as, poly-phenylenevinylene (PPV) series and polyfluorene series, may be used to form the EML.

The organic light-emitting devices 230 are electrically connected to the TFTs 220 installed thereunder. When a planarization film 217 covering the TFTs 220 is included, the organic light-emitting devices 230 are arranged on the planarization film 217, and the pixel electrodes 231 of the organic light-emitting devices 230 are electrically connected to the TFTs 220 via contact holes formed within the planarization film 217.

The organic light-emitting devices 230 formed on the substrate 100 are sealed are encapsulated by a sealing layer 400. The sealing layer 400 may be formed of various materials, such as, glass or plastic.

Some of the wires 310, 320, and 330 illustrated in FIG. 5 may be installed on the same level as the gate electrode 221, and some of the others may be installed on the same level as the source and drain electrodes 223. In other words, the wire 310 may be installed directly on the substrate 100, the wire 320 may be installed on the gate insulation film 213 formed on the substrate 100, and the wire 330 may be installed on the interlayer insulation layer 215 formed on the gate insulation film 213.

In this case, by adjusting the heights of the bumps 510, 520, and 530 of the chip 500 according to the levels on which the corresponding wires 310, 320, and 330 are installed, as described above, all of the bumps 510, 520, and 530 can be electrically connected to the corresponding wires 310, 320, and 330, respectively.

As described above, some of the wires 310, 320, and 330 shown in FIG. 5 may be formed on the same level as some of the electrodes of each of the TFTs. Alternatively, some of the wires 310, 320, and 330 shown in FIG. 5 may be formed on the same level as the pixel electrodes 231. As such, various modifications may be made.

Some of the wires 310, 320, and 330 shown in FIG. 5 may be arranged on the same level as not only the electrodes of the TFTs installed within the display unit but also electrodes of TFTs installed outside the display unit.

In the above-described embodiments, distances between the top surfaces of the wires and the end surfaces of the bumps electrically connected to the wires are made constant. However, the present invention is not limited to the constant distances between the wires and the bumps. In other words, the distances between the top surfaces of the wires and the end surfaces of the bumps electrically connected to the wires are not necessarily made constant, but the distances have only to be less than or equal to a diameter of each conductive spacer of a conduction film. Because the conductive spaces of the conductive film are elastic, when the distances between the top surfaces of the wires and the end surfaces of the bumps electrically connected to the wires are less than or equal to the diameter of each conductive spacer of the conduction film, the wires can be sufficiently electrically connected to the corresponding bumps.

The technique of making the distances between the top surfaces of the wires and the end surfaces of the bumps electrically connected to the wires constant, which is a feature of the present invention, can be applied not only to organic light-emitting display apparatuses but also to various flat panel display apparatuses having wires formed on a substrate, including liquid crystal display devices.

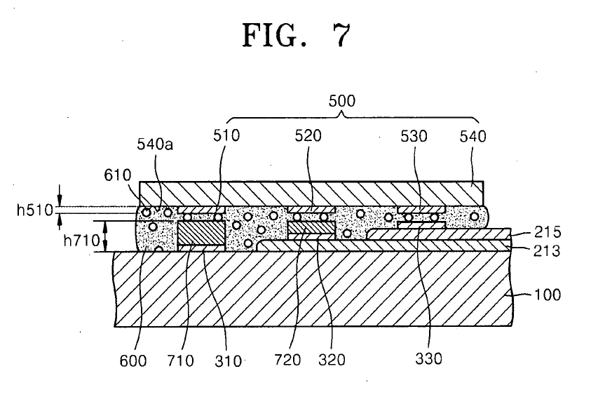

FIG. 7 is a schematic cross-section of a part of a flat panel display apparatus according to another embodiment of the present invention. The flat panel display apparatus of FIG. 7 is different from those according to the previous embodiments in that heights h510 of bumps 510, 520, and 530 of a chip 500 are constant and that pads 710 and 720 are installed between at least some of the wires 310, 320, and 330 and corresponding some of the bumps 510, 520, and 530.

The pads 710 and 720 contribute to a stable electrical connection of the bumps 510, 520, and 530 of the chip 500 to the wires 310, 320, and 330 although the heights of the bumps 510, 520, and 530 are always constant. In other words, even when heights from the top surface of the substrate 100 to the top surfaces of the wires 310, 320, and 330 are different, the pads 710 and 720 are arranged on the top surfaces of at least some of the wires 310, 320, and 330 so that heights h710 from the top surface of the substrate 100 to surfaces of the pads 710 and 720 facing the bumps 510 and 520 are constant. Accordingly, distances between the end surfaces of the bumps 510 and 520 and the top surface of the pads 710 and 720 are constant although the heights h510 of the bumps 510, 520, and 530 are constant. Thus, a stable electrical connection between the bumps 510 and 520 of the chip 500 and the pads 710 and 720 is achieved, leading to a stable electrical connection between the bumps 510, 520, and 530 of the chip 500 and the wires 310, 320, and 330. In this case, to electrically connect the bumps 510, 520, and 530 of the chip 500 to the wires 310, 320, and 330, the pads 710 and 720 may be formed of a conductive material.

Although it is illustrated in FIG. 7 that the pads 710 and 720 are arranged on only the wires 310 and 320 excluding the wire 330 arranged at the highest level over the top surface of the substrate 100, pads may be arranged on all of the wires 310, 320, and 330. In contrast with what is shown in FIG. 7, the conductive pads 710 and 720 may be connected to each other using a non-conductive material so as to be treated as one member. In this way, various modifications may be made.

In a flat panel display apparatus including a chip a chip according to an embodiment of the present invention as described above, the chip can be electrically connected to wires on a substrate without errors.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A flat panel display device comprising:
a substrate comprising a top surface;
a chip comprising a bottom surface and a plurality of bumps on the bottom surface, wherein the plurality of bumps comprise a first bump and a second bump, each bump comprising a bottom surface; and
a plurality of wires interposed between the top surface of the substrate and the bottom surface of the chip, the plurality of wires comprising a first wire and a second wire, each wire comprising a top surface,
wherein the first wire is aligned with the first bump in a direction substantially perpendicular to the top surface of the substrate, and the second wire is aligned with the second bump in said direction,
wherein a first distance between the top surface of the substrate and the top surface of the first wire is substantially different from a second distance between the top surface of the substrate and the top surface of the second wire, and
wherein a first interval between the top surface of the first wire and the bottom surface of the first bump is substantially identical to a second interval between the top surface of the second wire and the bottom surface of the second bump.

2. The device of claim 1, further comprising a selective conduction film, wherein the selective conduction film is interposed between the wires and bumps such that aligned pair of wire and bump are electrically connected to each other.

3. The device of claim 2, wherein the selective conduction film comprises an anisotropic conduction film.

4. The device of claim 2, wherein the selective conduction film comprises a plurality of conductive spacers, each of which having a spacing size by which the conductive spacer keeps two planes apart from each other.

5. The device of claim 4, wherein the spacing size of the conductive spacer is larger than the interval between the aligned pair of wire and bump.

6. The device of claim 4, wherein the conductive spacers comprise a plurality of conductive beads having a diameter, and wherein the diameter is larger than the interval between the aligned pair of wire and bump.

7. The device of claim 4, wherein the conductive beads are elastic.

8. The device of claim 1, wherein the chip further comprises a third bump and a fourth bump, each bump comprising a bottom surface, and wherein a third distance between the top surface of the substrate and the top surface of the third wire is substantially identical to a fourth distance between the top surface of the substrate and the top surface of the third wire.

9. The device of claim 1, further comprising a first layer having a first height from the top surface of the substrate and a second layer having a second height from the top surface of the substrate.

10. The device of claim 9, wherein the first wire is formed on the first layer and the second wire is formed on the second layer.

11. The device of claim 10, wherein the first height is different from the second height.

12. The device of claim 10, wherein the first height is substantially same as the second height.

13. The device of claim 10, wherein a first distance between the top surface of the substrate and the top surface of the first wire is different from the second distance between the top surface of the substrate and the top surface of the second wire.

14. The device of claim 10, wherein a first distance between the top surface of the substrate and the top surface of the first wire is substantially identical to a second distance between the top surface of the substrate and the top surface of the second wire.

15. The device of claim 9, wherein the first layer formed on at least part of the top surface of the substrate and the second layer formed on at least part of the top surface or on at least part of the first layer.

16. The device of claim 1, wherein a first distance between the top surface of the substrate and the bottom surface of the first bump is different from a second distance between the top surface of the substrate and the bottom surface of the second bump.

17. The device of claim 1, wherein a first distance between the top surface of the substrate and the bottom surface of the first bump is substantially identical to a second distance between the top surface of the substrate and the bottom surface of the second bump.

18. A flat panel display device comprising:
a substrate comprising a top surface;
a chip comprising a bottom surface and a plurality of bumps on the bottom surface, wherein the plurality of bumps comprise a first bump and a second bump, each bump comprising a bottom surface;
a plurality of wires interposed between the top surface of the substrate and the bottom surface of the chip, the plurality of wires comprising a first wire and a second wire, each wire comprising a top surface; and
a conductive pad formed on the top surface of the wire, wherein the conductive pad is made of a material different from that of the second wire, wherein the conductive pad has a top surface facing the bottom surface of the second bump,
wherein the first wire is aligned with the first bump in a direction substantially perpendicular to the top surface of the substrate, and the second wire is aligned with the second bump in said direction, wherein a first distance between the top surface of the substrate and the top surface of the first wire is substantially different from a second distance between the top surface of the substrate and the top surface of the second wire, and wherein the distance between the top surface of the conductive pad and the top surface of the substrate is substantially identical to the first distance.
